(19) United States
(12) Patent Application Publication
(10) Pub. No.: US 2015/0184053 A1
(43) Pub. Date: Jul. 2, 2015

(54) GASKETTED THERMAL INTERFACE

(71) Applicants: SHANKAR KRISHNAN, Wilsonville, OR (US); Susan F. Smith, Olympia, WA (US); CHRISTIAN AK AMOAH-KUSI, Portland, OR (US); Jeffory L. Smalley, East Olympia, WA (US); Barrett M. Faneuf, Beaverton, OR (US); Jeremy Young, Hillsboro, OR (US); Tao Liu, Dupont, WA (US); loan Sauciuc, Phoenix, AZ (US)

(72) Inventors: SHANKAR KRISHNAN, Wilsonville, OR (US); Susan F. Smith, Olympia, WA (US); CHRISTIAN AK AMOAH-KUSI, Portland, OR (US); Jeffory L. Smalley, East Olympia, WA (US); Barrett M. Faneuf, Beaverton, OR (US); Jeremy Young, Hillsboro, OR (US); Tao Liu, Dupont, WA (US); loan Sauciuc, Phoenix, AZ (US)

(21) Appl. No.: 14/142,704

(22) Filed: Dec. 27, 2013

(51) Int. Cl. C09K 5/06; B23P 15/26; H05K 7/20; F28F 23/00

(52) U.S. Cl. CPC C09K 5/06; F28F 23/00; B23P 15/26; H05K 7/2029; H05K 7/2039

(57) ABSTRACT

A gasketted thermal interface material (TIM) is described herein. The gasketted TIM includes a phase change thermal interface material and a curable thermal interface material. The curable thermal interface material surrounds the phase change thermal interface material. The gasketted TIM also includes a gasketted chamber, and the phase change thermal interface material is located within the gasketted chamber.

### TECHNICAL FIELD

This disclosure relates generally to a gasketted thermal interface material. More specifically, the disclosure describes a gasketted thermal interface material including a curable thermal interface material and phase-change thermal interface.

### BACKGROUND ART

Modern electronic devices often generate a substantial amount of heat, due to their density and size. Further, many electronic devices have embody a structure that can trap heat around its internal components. For example, all-in-one computing (AIO) computing systems may include a monitor, power supply, mother board, and any drives used to implement a standard desktop computer system in a single enclosure. With such varied components in operation, the amount of excessive heat generated may be greater than the amount of heat removed from the system, thus, potentially leading to system performance issues. Therefore, heat generated in an electronic device should be dissipated or removed to improve performance reliability and to prevent premature device failures.

### BRIEF DESCRIPTION OF THE DRAWINGS

FIG. 1A is an illustration of a cross-sectional view of a contacting surface and a contacting surface gap;

FIG. 1B is a cross-sectional view of a TIM between the contacting surface and a contacting surface structures to partially fill the air gaps;

FIG. 2A is an illustration of an isothermal bake sample 200 without a gasketted curable gap filler thermal interface material (TIM) before baking

FIG. 2B is an illustration of an isothermal bake sample 210 without a gasketted curable thermal interface material (TIM) 202 after baking

FIG. 2C is an illustration of an isothermal bake sample 220 without a gasketted curable gap thermal interface material (TIM) 202 after baking with pump out

FIG. 3A is an illustration of an isothermal bake sample 300 with a gasketted curable thermal interface material (TIM) 304 before baking;

FIG. 3B is an illustration of an isothermal bake sample 310 with a gasketted curable thermal interface material (TIM) 304 after baking;

FIG. 4 is an illustration of a cross-section view of an electronic device 400 including the gasketted thermal interface material; and

FIG. 5A is an illustration showing a mobile TIM with an immobile TIM 504;

FIG. 5B is another illustration showing a mobile TIM with an immobile TIM 504;

FIG. 5C is an illustration showing a mobile TIM, a second mobile TIM, and an immobile TIM 504;

FIG. 6 is a process flow diagram describing a method of forming a gasketted thermal interface material.

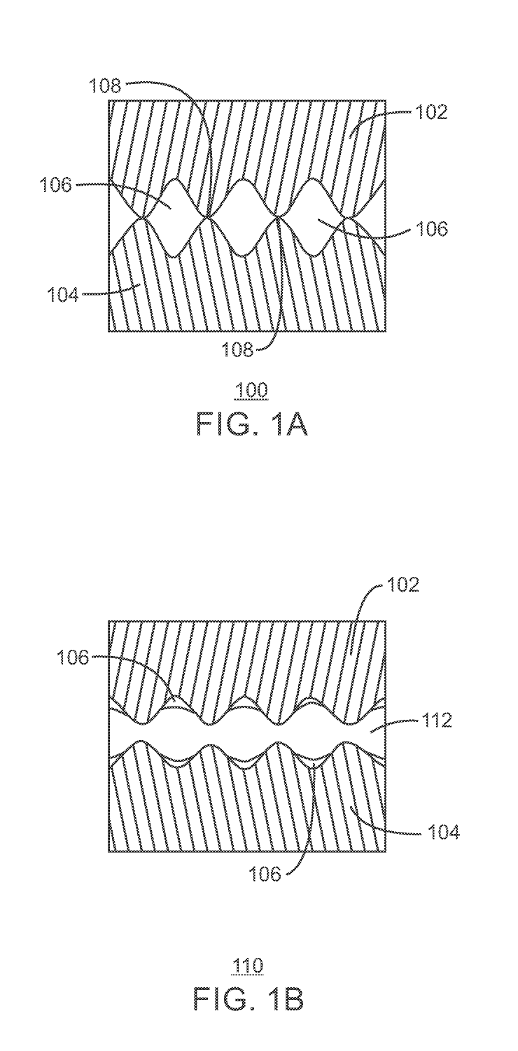

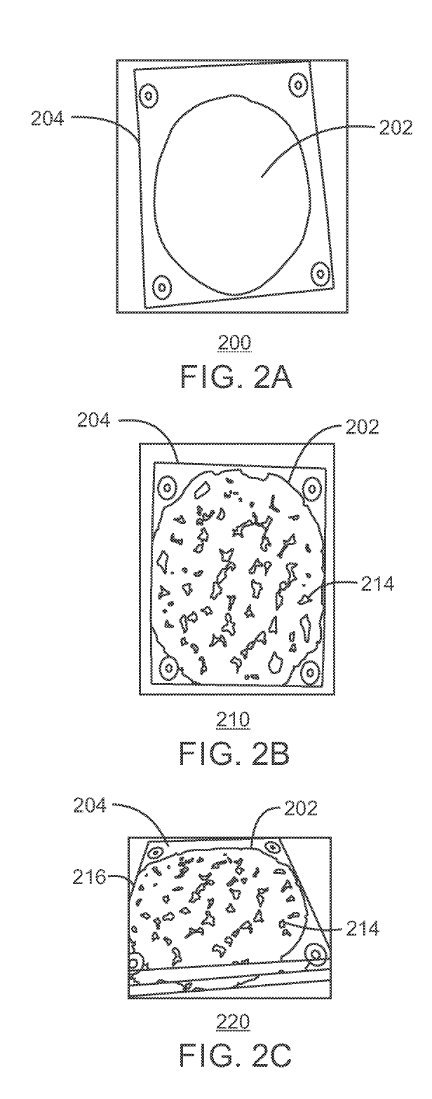

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

When an electronic device includes both high-power density components and low-power density components, a combination of heat-dissipating techniques may be implemented to adequately remove heat from the device. For example, low-power components may not require heat dissipation materials embodying high bulk conductivity, since at low-power conditions the cooling difference between low and high bulk conductivity material may be slight. Conversely, high-power components can require heat dissipation materials with a low impedance, i.e., thin and conductive in nature, or the cooling capacity of a heat sink. Thus, a heat dissipating material should facilitate a low thermal impedance for variations in size of a contact area and coplanar/non-coplanar variations within both low-power and high-power components.

There are many well-known heat-dissipating materials techniques and materials including heat sinks, air and liquid cooling mechanisms, thermal interface materials, among others. In particular, thermal interface materials (TIM) may be often used when two commercial grade surfaces are brought into physical contact with one another. Such surfaces may be characterized by a surface roughness superimposed the generally planar surface such that cause the surfaces to have small areas that are concave, convex, or twisted in shape. Additionally, when the two surfaces are physically joined together, the contact between the surfaces may only occur at a contact point so that low points may form air-filled gaps. In some cases, the contact area is the interface between the surfaces. The contact area can consist of up to 90% air-filled gaps when the TIM is a viscous fluid substance between the surfaces, The air gaps represent a significant resistance to heat dissipation and an adverse impact on heat conduction between the interface gap.

Embodiments described herein relate to a gasketted thermal interface material. The gasketted TIM includes a phase change thermal interface material and a curable thermal interface material. The curable thermal interface material surrounds the phase change thermal interface material. The gasketted TIM also includes a gasketted chamber, and the phase change thermal interface material is located within the gasketted chamber. In this manner, the gasketted TIM significantly reduces air gaps from the interface between the two contacting surfaces. Since a TIM can have a greater thermal conductivity than the air it displaces, the thermal resistance between the two contacting surfaces may decrease leading an efficient transfer of heat from the surfaces. Moreover, the gasketted TIM can be used with both low-power and high-power components.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the inventions. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

FIG. 1A is an illustration of a cross-sectional view of a contacting surface 102 and a contacting surface 104 gap. FIG. 1A illustrates a substantially planar contacting surface 102 and a substantially planar contacting surface 104, that when magnified many times show small areas that are that are concave, convex, and twisted. In some cases, one of the contacting surfaces may be a heat dissipating component and the other contacting surfaces may be a heat generating component. For example, the heat dissipating component may be a thermal management component that transfers heat away from the heat generating component, such as a heat sink. The heat generating component may be a system or device where heat is generated as a normal by-product of the system operations such as a CPU or integrated circuit package. In operation, the heat dissipating component aids in moving heat away from the heat generating component. The contacting surface 102 and the contacting surface 104 may be mated under pressure. However, as illustrated in FIG. 1A, the physical contact between the contacting surface 102 and the contacting surface 104 is not continuous, and small areas between the contacting surface 102 and the contacting surface 104 are concave, convex, and possibly twisted along the generally planar contacting surface. These small areas that are not planar may cause several air gaps 106 between the contacting surfaces. Such surface irregularities can prevent direct contact of specific areas between the mating surfaces of the contacting surface 102 and the contacting surface 104. Several solid contacts 108 occur between the contacting surface 102 and the contacting surface 104, leaving the air gaps 106 between low lying areas. Most of the heat transfer takes place via the solid contacts 108, and the number of these solid contacts 108 may be restricted if the substantially planar surface is rough. A small amount of heat transfer may occur through the air gap 106 since the thermal conductivity of air may be relatively insignificant compared to the thermal conductivity of the material of the contacting surface that is a heat dissipation component. However, the air gaps 106 may limit heat from the heat generating component into the heat dissipation component. This can result in a build-up of heat within the heat generating component, and can ultimately lead to failure of an entire system including the heat generating component.

FIG. 1B is a cross-sectional view 110 of a TIM 112 between the contacting surface 102 and a contacting surface 104 structure to partially fill the air gaps 106. In order to eliminate the air gaps 106 and improve thermal transfer, a TIM may be used. As illustrated in FIG. 1B, the TIM 112 conforms to the air gaps 106 by displacing the air, thus, providing more area for heat to flow and reducing the thermal resistance of the interface of the contacting surface 102 and a contacting surface 104. However, the TIM 112 of FIG. 1B may not completely fill the air gaps 106. Thus, performance of the contacting surface 102 and a contacting surface 104 may deteriorate over time since excessive heat remains between the contacting surface 102 and the contacting surface 104.

There are currently several types of TIMs available for use, including thermal greases, thermal tapes, gap filling thermal pads, phase-change materials, elastomers, and carbon based materials. Many TIMs include a base material with added fillers such as ceramic particles, to increase thermal conductivity relative to the base material. The base material may include greases, polymers, and the like. In embodiments, the TIM may include an immobile TIM and a mobile TIM. The immobile TIM may be any low bleed material, such as a curable thermal interface material, an elastomer or an polymeric matrix with a filler, where the elastomer or an polymeric matrix is in the form of an adhesive, encapsulant, or gel. The cure time and cure temperatures for the curable TIM may vary based on the product selected.

The mobile TIM may include a low viscosity material having a liquid consistency, such as a phase-change material, a liquid phase thermal interface material, and the like. A phase-change thermal interface material (TIM) is characterized by its ability to change its physical characteristics. At room temperature, the phase-change TIM is typically firm and easy to handle, and can be injected or deposited on a surface as a liquid. This may allow for more control when applying the material between a heat-dissipating surface and a heat generating component. After heat is applied, the phase-change material may change to a soft aggregate state at a pre-defined temperature or the “phase-change temperature” to optimize heat transfer and improve the reliability of an electronic device during thermal cycling. In operation, a phase-change TIM may fill air gaps or voids between the heat-dissipating surface and the heat generating component by conforming to the uneven contacting surfaces or mating surfaces of the components before turning into a solid after cooling. In some cases, the phase change TIM may also be called a thermal pad. Additionally, in some cases, the mobile thermal interface material has a phase change starting at about 45° C. Moreover, the mobile thermal interface material has a thermal conductivity ranging from about 2.0 to about 5.0 W/m° C. Furthermore, in some cases the thermal conductivity range of the mobile TIM and immobile TIM is about 1 watt per meter Kelvin (W/mK) to 90 W/mK.

FIG. 2A is an illustration of an isothermal bake sample 200 without a gasketted curable gap filler thermal interface material (TIM) before baking. Particularly, FIG. 2A shows a sample of a phase-change TIM 202 in a laboratory setting before being subjected to heat. The phase-change TIM may be deposited on a glass baking sheet 204 and subjected to a temperature of about 120° C. in a baking oven. In some embodiments, the phase-change TIM 202 may be a thermal paste.

FIG. 2B is an illustration of an isothermal bake sample 210 without a gasketted curable thermal interface material (TIM) 202 after baking. As shown in FIG. 2B, the isothermal bake sample 210 may exhibit large air gap 214 formation through the phase-change TIM 202. The air gaps 214 in the phase-change TIM 202 may be trapped during the flow of the TIM 202 during assembly due to outgassing during the curing process or due to insufficient volume. Additionally, such air gap 214 formation and composition change may be induced by mass transport within the phase-change TIM 202. Such air gap formation and compositional change may cause endurance, structural, and reliability problems in the phase-change TIM.

FIG. 2C is an illustration of an isothermal bake sample 220 without a gasketted curable gap thermal interface material (TIM) 202 after baking with pump out. When subjected to continuous pressure, the phase-change TIM 202 may pump-out or flow out of an interface and into to neighboring areas during thermal cycling. Since the phase-change TIM may flow between an interface of two components to fill gaps, some compressive force may be added to bring the two surfaces together and cause the material to flow. The pump-out is illustrated at reference number 216 with the thermal interface material escaping from the edge of the glass baking sheet. The pump-out may lead to potential contamination of neighboring components or drying of the interface.

In operation, pump-out or the drying action may result from the mobility of the phase-change TIM. At certain temperatures, the phase-change TIM may have its viscosity lowered so that at an interface of two components, there may be a competition between the natural capillary forces that hold the phase-change TIM inside of the interface and the surface tension of the phase-change TIM to the components. Thus, as pressure is applied or as surface tension rise, the phase-change TIM may migrate out from the components and thus dry-out over time due to exposure.

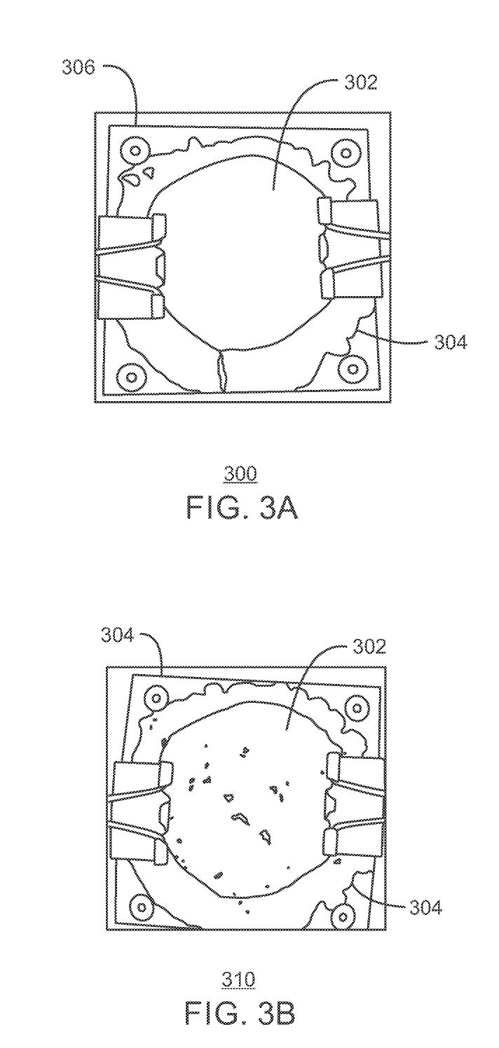

FIG. 3A is an illustration of an isothermal bake sample 300 with a gasketted curable thermal interface material (TIM) 304 before baking. As shown in FIG. 3A, a phase-change TIM 302 is surrounded by a gasketted curable TIM 304. The gasketted curable TIM 304 may be stenciled onto the glass baking sheet 306 to surround the phase-change TIM 302. In some embodiments, the gasketted curable TIM 304 may be needle dispensed, screen printed, or manually applied to the glass baking sheet. The phase-change TIM 302 may be located in a gasketted chamber or an interfacial voided area located within a cross-sectional area of the gasketted curable TIM 304, which surrounds the phase-change TIM 302.

The gasketted curable TIM may be an immobile TIM that provides a barrier for preventing pump-out of the phase-change TIM. Additionally, the phase-change TIM may act as a mobile TIM. The gasketted curable TIM may be an elastomeric gap pad or insulator, a curable gel, or thermal grease. When assembled together, the curable TIM and the phase-change TIM may form the gasketted curable TIM to accommodate dynamic warping or shape change of components under thermochemical stress due to thermal cycling and compressive forces.

FIG. 3B is an illustration of an isothermal bake sample 310 with a gasketted curable thermal interface material (TIM) 304 after baking. As illustrated in FIG. 3B, when subjected to a temperature of about 120° C. in a baking oven, the gasketted curable TIM 304 may enable a reduction in the formation of gaps with no pump-out of the phase change TIM 302. The gasketted curable TIM 304, and the phase-change TIM 302 may incorporate an assortment of thermal interface materials including both immobile and mobile TIMs. The combination of both an immobile TIM and a mobile TIM may facilitate cost reduction along with both a low pre-load pressure design and a high pre-load pressure design along with high performance for high-power devices and low performance for low-power devices. The ability of the gasketted curable TIM to handle a variety of scenarios may allow a user to strategically place the phase-change TIM near cooler, low-power devices while enabling the higher performance curable TIM near higher power density parts. The gasketted curable TIM alone may be able to handle the adsorption of dynamic warping in the areas where the low performance/density devices are located, as well as, the location of the high performance/density devices. In embodiments, the gasketted TIM is subjected to a temperature range of about 120° C. to 400° C.

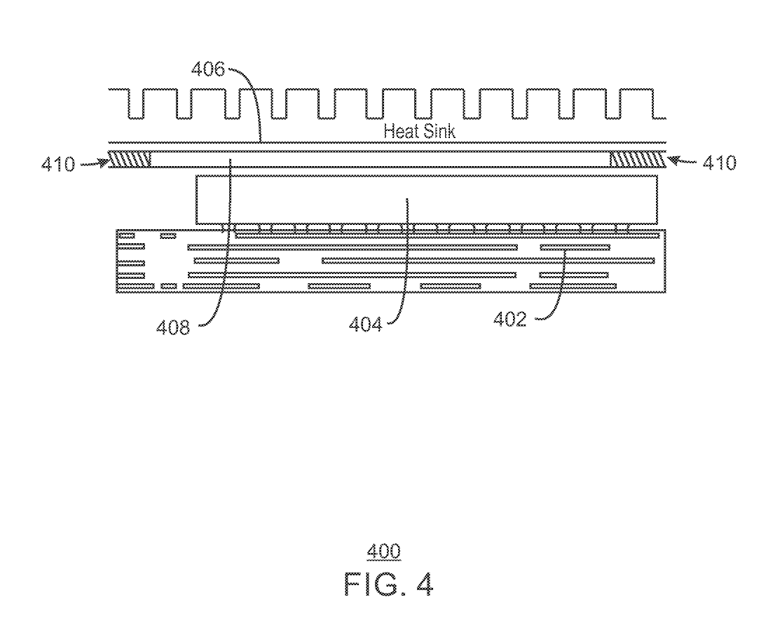

FIG. 4 is an illustration of a cross-section view of an electronic device 400 including the gasketted thermal interface material. A printed circuit board (PCB) 402 is coupled with a heat generating component 404. The heat generating component can be a system or device where heat is generated as a normal by-product of the system. In examples, the heat generating component is CPU, integrated circuit package, microprocessor, memory device, or the like. Electronic device 400 includes a heat sink 406 that is a heat dissipating component that draws heat away from the heat generating component 404.

A TIM 408 is located between the heat generating component 404 and the heat sink 406. The TIM 408 may be a mobile TIM. The TIM 408 is surrounded by a gasketted curable TIM 410. The TIM 410 may be an immobile TIM. Additionally, in some cases the TIM 410 is a gap pad. The gap pad can be strategically placed as a gasketting material while another TIM, such as a thermal paste, is placed within the gasketted chamber formed by the gap pad. When the heat generating component 404 and the heat sink 406 are pressed together, the gasketted curable TIM 410 prevents pump-out or leakage of the TIM 408 into undesirable areas of the electronic device 400. In some cases the TIM 408 is a phase change material that is a solid or thick gel when at lower temperatures, and change to a more fluid substance as temperatures increase. In this manner, the phase change material offers the thermal performance of a thermal paste or grease while being easily handled or installed. The phase change material can be used between high performance microprocessors and heat sinks. The phase change material materials may not experience a true phase change, however, the viscosity of the material does diminish rapidly. This enables the phase change material to flow throughout a thermal cavity to fill any air gaps that were initially present. In some cases, force is applied to bring two contacting surfaces together to cause the phase change material to flow. In some cases, the TIM 408 is a thermally conductive gap filler. The thermally conductive gap filler may be a thermally conductive silicone elastomer. Such a material is appropriate to fill a large gap between the contacting surfaces.

In some cases, the TIM 410 is a thermally conductive compounds that is cured in place. The curable compound can be reactive such that is cures into a firm compound when heat is applied. In embodiments, the curable compound forms a gasket surrounding a more viscous TIM. Moreover, in embodiments, the curable compound, is a one or multi-part silicone RTV (room temperature vulcanizing) compound or a similar compound that can be used to for heat dissipation where the distance between the contacting surfaces is highly variable.

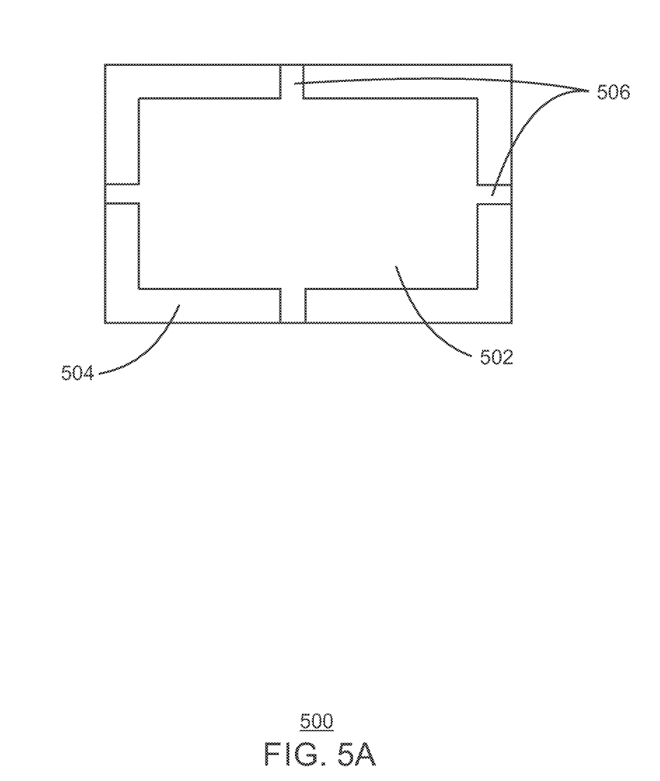

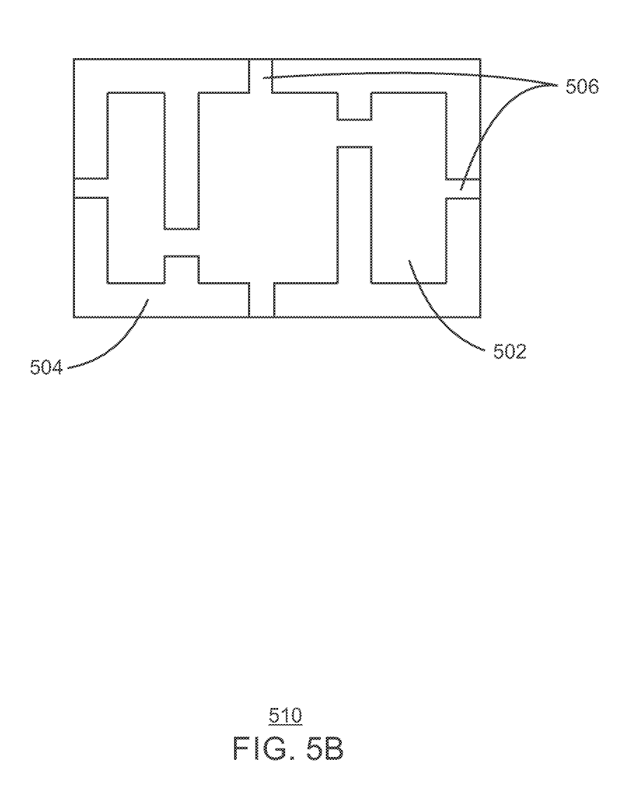

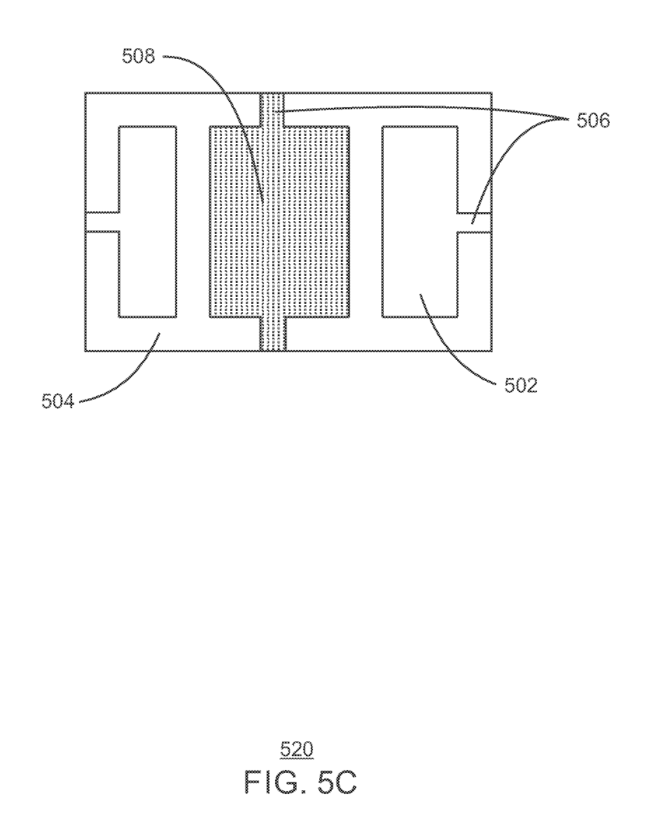

FIG. 5A is an illustration 500 showing a mobile TIM 502 with an immobile TIM 504. The mobile TIM 502 is located within borders defined by the immobile TIM 504. The immobile TIM 504 is separated by a plurality of vents or drains 506 that enable draining of excess mobile TIM 502 from the interior of the gasketted chamber. Although four vents or drains 506 are illustrated, any number of vents or drains 506 may be used.

FIG. 5B is an illustration 510 showing a mobile TIM 502 with an immobile TIM 504. The mobile TIM 502 is located within borders defined by the immobile TIM 504. The immobile TIM 504 is separated by a plurality of vents or drains 506 that enable draining of excess mobile TIM 502 from the interior of the gasketted chamber. The immobile TIM extends throughout the mobile TIM 502. In this manner, multiple gasketted chambers can be used to manage bondlines, dynamic warpage, and the like.

FIG. 5C is an illustration 520 showing a mobile TIM 502, a second mobile TIM 508, and an immobile TIM 504. The mobile TIM 502 is located within borders defined by the immobile TIM 504. The immobile TIM 504 is separated by a plurality of vents or drains 506 that enable draining of excess mobile. The immobile TIM extends throughout the mobile TIM 502. In this manner, multiple gasketted chambers TIM 502 form the interior of the gasketted chamber. Additionally, a second mobile TIM 508. In this manner, multiple gasketted chambers can be used with multiple “mobile” TIMs. This enables cheaper mobile TIMs to be used for low power components, while high performance mobile TIMS are used with high power components.

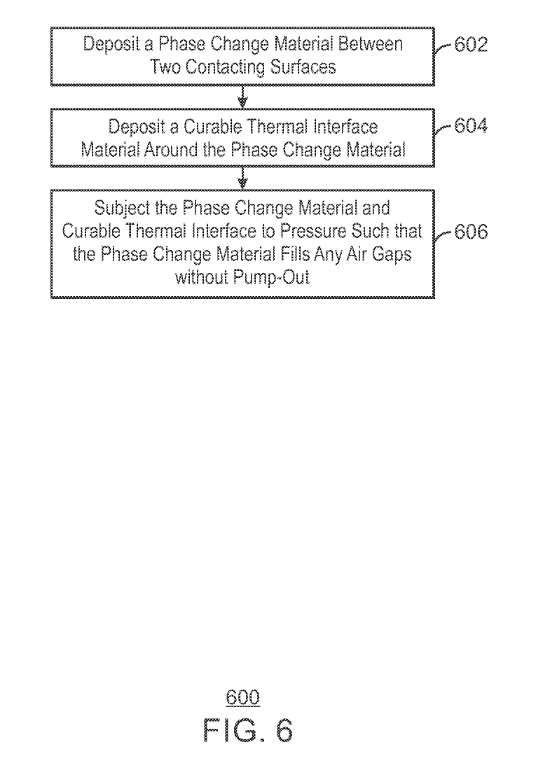

FIG. 6 is a process flow diagram describing a method of forming a gasketted thermal interface material. At block 602, a phase change thermal interface material is deposited between a first contacting surface and a second contacting surface. The phase change thermal interface material is located in a gasketted chamber. At block 604, a curable thermal interface material is deposited between the two contacting surfaces to surround the phase change thermal interface material. At block 606, the phase change thermal interface material and the curable thermal interface material are subjected to pressure, such that the phase change material and the curable thermal interface material fills any air gaps between the two contacting surfaces without pump-out. In this manner, the present techniques enables cheaper TIM solutions for large packages, while strategically placing low-performance TIMs to cool low-power devices under the lid and high performance TIMs for high power density parts.

Although operations may be described as a sequential process, some of the operations may in fact be performed in parallel, concurrently, and/or in a distributed environment. In addition, in some embodiments the order of operations may be rearranged without departing from the spirit of the disclosed subject matter.

### EXAMPLE 1

A gasketted thermal interface material is described herein. The gasketted thermal interface material includes a mobile thermal interface material and an immobile thermal interface material. The immobile thermal interface material surrounds the mobile thermal interface material. The gasketted thermal interface material also includes a gasketted chamber, the mobile thermal interface material is located within the gasketted chamber.

The immobile thermal interface material may be a curable elastomer, and the curable elastomer has slight adhesive properties. Additionally, the immobile thermal interface material may be a thermally conductive material with a thermal conductivity in a range of about 2.5 to 4.5 W/m° C. The immobile thermal interface material may be stenciled around the mobile thermal interface material. Further, the immobile thermal interface material can be a barrier to prevent the flow of the mobile thermal interface material. The immobile thermal interface material may be placed in close proximity to high-power devices, and the mobile thermal interface material may be placed in close proximity to low-power devices. The mobile thermal interface material may have a phase change starting at about 45° C., and the mobile thermal interface material may have a thermal conductivity ranging from about 2.0 to about 5.0 W/m° C. Moreover, the gasketted TIM may be subjected to a temperature range of about 120° C. to 400° C. The gasketted TIM may also be placed between two heat dissipating structures.

### EXAMPLE 2

An electronic device is described herein. The electronic device includes a gasketted thermal interface material, a heat dissipating structure, and a heat generating component. The gasketted thermal interface material may include a curable thermal interface material and a phase change thermal interface material. The gasketted thermal interface material may be located between the heat dissipating structure and the heat generating component. Additionally, the gasketted thermal interface material may fill in gaps between the heat dissipating structure and the power generating component. The curable thermal interface material may surround the phase change thermal interface material. Moreover, the curable thermal interface material may limit the amount of pump out the phase change thermal interface material.

### EXAMPLE 3

A method for forming a gasketted thermal interface material (TIM) is described herein. The method includes depositing a phase change thermal interface material between a first contacting surface and a second contacting surface, wherein the phase change thermal interface material is located in a gasketted chamber. The method also includes depositing a curable thermal interface material between the two contacting surfaces to surround the phase change thermal interface material. Additionally, the method includes subjecting the phase change thermal interface material and the curable thermal interface material to pressure such that the phase change material and the curable thermal interface material fills any air gaps between the two contacting surfaces without pump-out. The curable thermal interface material may be stenciled or screen printed onto one of the contacting surfaces. Moreover, the phase change thermal interface material is a gap pad.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the present techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. A gasketted thermal interface material (TIM), comprising:
a mobile thermal interface material;
an immobile thermal interface material, wherein the immobile thermal interface material surrounds the mobile thermal interface material; and
a gasketted chamber, wherein the mobile thermal interface material is located within the gasketted chamber.

2. The gasketted TIM of claim 1, wherein the immobile thermal interface material is a curable elastomer, and the curable elastomer has slight adhesive properties.

3. The gasketted TIM of claim 1, wherein the immobile thermal interface material is a thermally conductive material with a thermal conductivity in a range of about 2.5 to 4.5 W/m° C.

4. The gasketted TIM of claim 1, wherein the immobile thermal interface material is stenciled around the mobile thermal interface material.

5. The gasketted TIM of claim 1, wherein the immobile thermal interface material is a barrier to prevent the flow of the mobile thermal interface material.

6. The gasketted TIM of claim 1, wherein the immobile thermal interface material is placed in close proximity to high-power devices.

7. The gasketted TIM of claim 1, wherein the mobile thermal interface material is placed in close proximity to low-power devices.

8. The gasketted TIM of claim 1, wherein the mobile thermal interface material has a phase change starting at about 45° C.

9. The gasketted TIM of claim 1, wherein the mobile thermal interface material has a thermal conductivity ranging from about 2.0 to about 5.0 W/m° C.

10. The gasketted TIM of claim 1, wherein the gasketted TIM is subjected to a temperature range of about 120° C. to 400° C.

11. The gasketted TIM of claim 1, wherein the gasketted TIM is placed between two heat dissipating structures.

12. An electronic device, comprising
a gasketted thermal interface material;
a heat dissipating structure; and
a heat generating component

13. The electronic device of claim 12, wherein the gasketted thermal interface material includes a curable thermal interface material and a phase change thermal interface material.

14. The electronic device of claim 12, wherein the gasketted thermal interface material is located between the heat dissipating structure and the heat generating component.

15. The electronic device of claim 12, wherein the gasketted thermal interface material fills in gaps between the heat dissipating structure and the power generating component.

16. The electronic device of claim 12, wherein the curable thermal interface material surrounds the phase change thermal interface material.

17. The electronic device of claim 12, wherein the curable thermal interface material limits the amount of pump out the phase change thermal interface material.

18. A method for forming a gasketted thermal interface material (TIM), comprising:
depositing a phase change thermal interface material between a first contacting surface and a second contacting surface, wherein the phase change thermal interface material is located in a gasketted chamber;
depositing a curable thermal interface material between the two contacting surfaces to surround the phase change thermal interface material; and
subjecting the phase change thermal interface material and the curable thermal interface material to pressure such that the phase change material and the curable thermal interface material fills any air gaps between the two contacting surfaces without pump-out.

19. The method of claim 18, wherein the curable thermal interface material is stenciled or screen printed onto one of the contacting surfaces.

20. The method of claim 18, wherein the phase change thermal interface material is a gap pad.
